(19) United States
(12) Patent Application Publication
(10) Pub. No.: US 2011/0308577 A1
(43) Pub. Date: Dec. 22, 2011

(54) PHOTOVOLTAIC PANEL AND METHOD OF MANUFACTURING THE SAME

(75) Inventor: Stephen Yau-Sang CHENG, Sheung Shui (HK)

(73) Assignee: Du Pont Apollo Limited

(21) Appl. No.: 13/164,774

(22) Filed: Jun. 21, 2011

Related U.S. Application Data
(60) Provisional application No. 61/357,098, filed on Jun. 22, 2010.

(51) Int. Cl. H01L 31/048; H01L 31/18

(52) U.S. Cl. 136/251; 438/64; 257/E31.117

(57) ABSTRACT

Disclosed herein are a photovoltaic panel and a method of manufacturing the same. The photovoltaic panel includes a photovoltaic unit having a single substrate and a protective polymer layer wrapping around the photovoltaic unit and being sealed around the edges of a surface of the substrate. The manufacturing method includes the steps of providing a substrate, forming a photovoltaic cell on a first surface of the substrate to form a photovoltaic unit, wrapping a protective polymer layer around the photovoltaic unit with a portion of the protective polymer layer extended beyond the first surface, and thermal treating the protective polymer layer so as to shrink the to protective polymer layer and thereby sealing the portion of the protective polymer layer extended beyond the first surface of the substrate around the edges of the second surface.

### RELATED APPLICATIONS

This application claims priority to U.S. Provisional Application Serial Number 61/357,098, filed Jun. 22, 2010, which is herein incorporated by reference.

### BACKGROUND

1. Technical Field

The present disclosure relates to an energy conversion device. More particularly, the present disclosure relates to a photovoltaic panel and a method of manufacturing the photovoltaic panel.

2. Description of Related Art

Solar energy has gained many research attentions for being a seemingly inexhaustible energy source. In order to effectively utilizing the solar energy, photovoltaic (PV) devices that convert solar energy into electrical energy are developed. The electrical energy generated by the photovoltaic devices can be used for all kinds of purposes as those generated by batteries or existing power generators. Recently, along with the progresses and developments of photovoltaic technology, the cost of the PV devices drops noticeably and thus the PV devices are getting more and more popular on the market.

Generally, the fabrication of a PV device involves a heat lamination process. For example, in the case of an amorphous silicon module, a polymer back sheet is laminated onto the glass/thin-film cell using an EVA encapsulant, or a glass backsheet is laminated onto the glass/thin-film cell using PVB or ionomer encapsulant. The process of heat lamination by using aforementioned encapsulant usually requires a temperature higher than 100° C. for more than 10 minutes, so as to ensure the stability and durability of the PV device for outdoor applications like solar farms or building-integrated photovoltaic (BIPV).

However, when the PV devices are used in consumer products like toys or digital watches, the PV devices do not need to work under harsh outdoor environments. In these cases, the high temperature process and the materials selected for the high temperature process make these PV devices over-engineered and thus render the PV devices in a relative high cost. Applying these relative high cost PV devices in consumer products would be uneconomic.

### SUMMARY

A photovoltaic panel and a method of manufacturing the photovoltaic panel are provided in the disclosure to solve the problems of over-engineered and relative high cost of applying the PV devices.

According to one aspect of the disclosure, a photovoltaic panel for converting a number of incoming light beams into electrical energy is provided. The photovoltaic panel includes a photovoltaic unit and a protective polymer layer. The photovoltaic unit is characterized in having a single substrate and comprising the single substrate and a photovoltaic cell. The single substrate has a first surface and an opposite second surface. The photovoltaic cell is disposed on the first surface. The photovoltaic unit is wrapped in the protective polymer layer, and the protective polymer layer is sealed around the edges of the second surface of the single substrate.

In one embodiment, the protective polymer layer is a heat-shrink film and includes a material selected from the group consisting of polyvinylchloride (PVC), polypropylene (PP), polyethylene (PE), polyethylene terephthalate (PET), polystyrene (PS), acrylonitrile-butadiene-styrene terpolymer (ABS), polycarbonate (PC), polylactic acid (PLA), and any combinations thereof.

In a further embodiment, the first surface faces the incoming light beams and the photovoltaic cell includes an electric contact for connecting to an electric junction box. The electric junction box is disposed next to the photovoltaic unit. The protective polymer layer includes an opening from which the electric contact is exposed.

In another embodiment, the second surface faces the incoming light beams and the electric junction box is disposed on the photovoltaic unit. In yet another embodiment, the photovoltaic unit further includes an electric circuitry connected to the electric contact, and the protective polymer layer covers the electric circuitry.

In yet another embodiment, the photovoltaic panel includes a sealant disposed around the edges of the first surface, or the edges of the second surface, to seal the protective polymer layer.

In yet another embodiment, the electric circuitry includes a flexible circuit and a metal wiring.

In yet another embodiment, the single substrate is a glass substrate, polymer sheet, stainless steel, aluminum or graphite.

In yet another embodiment, the photovoltaic cell is a crystalline silicon solar cell or a thin film solar cell.

According to another aspect of the disclosure, a method of manufacturing a photovoltaic panel is provided. The method includes the steps of providing a substrate having a first surface and an opposite second surface, forming a photovoltaic cell on the first surface to form a photovoltaic unit, wrapping a protective polymer layer around the photovoltaic unit with a portion of the protective polymer layer extended beyond the first surface of the substrate, and thermal treating the protective polymer layer so as to shrink the protective polymer layer and thereby sealing the portion of the protective polymer layer extended beyond the first surface of the substrate around the edges of the second surface.

In one embodiment, the method further includes the step of applying a sealant at or near the edges of the first surface prior to the step of wrapping the protective polymer layer around the photovoltaic unit.

In another embodiment, the method further includes the step of applying a sealant at or near the edges of the second surface prior to the step of wrapping the protective polymer layer around the photovoltaic unit.

In yet another embodiment, the method further includes the step of trimming the thermal treated protective polymer layer.

In the foregoing, the photovoltaic unit is wrapped in the protective polymer layer and is characterized in having a single substrate. The structure of the photovoltaic panel is therefore simplified and the cost is lowered by replacing a back sheet or a substrate with the protective polymer layer. Further, the efficiency of the manufacturing process is increased accordingly.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments, with reference made to the accompanying drawings as follows:

FIG. 1 is a flow chart of a method of manufacturing a photovoltaic panel according to one embodiment of the disclosure;

FIGS. 2A-2E are cross-sectional views of the photovoltaic panel in accordance with each step in FIG. 1;

FIG. 3 is a cross-sectional view of a photovoltaic panel according to another embodiment of the disclosure; and

FIG. 4 is a cross-sectional view of a photovoltaic panel according to a further embodiment of the disclosure.

### DETAILED DESCRIPTION

The photovoltaic panel and the method of manufacturing the photovoltaic panel utilize a protective polymer layer to wrap the photovoltaic unit, and the photovoltaic unit is characterized in having a single substrate. Therefore the structure of the photovoltaic panel is simplified, the cost is lowered, and the efficiency of the manufacturing process is increased.

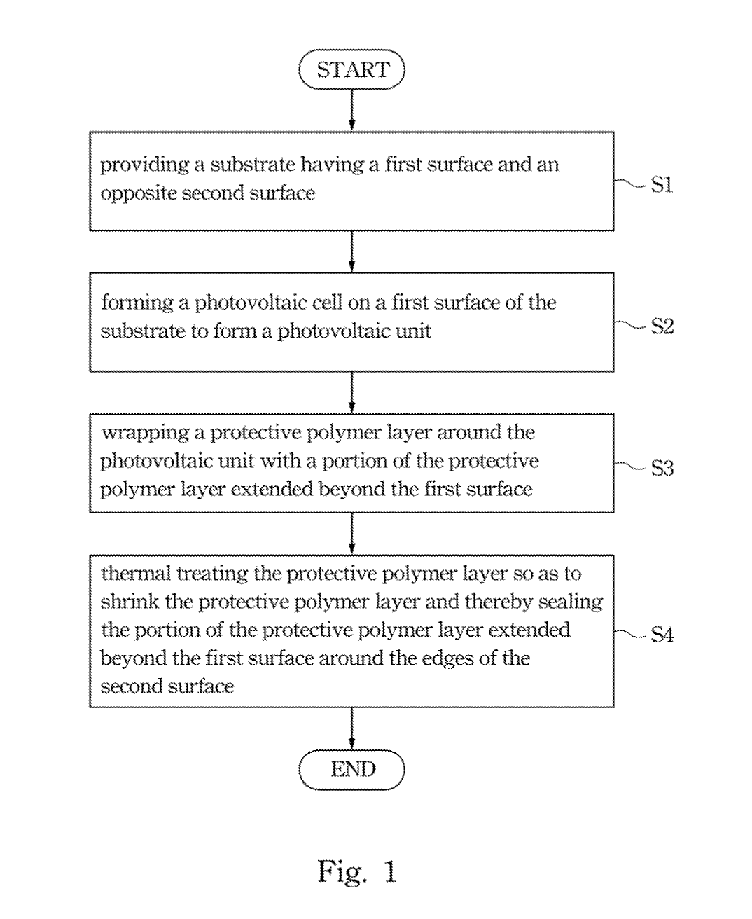

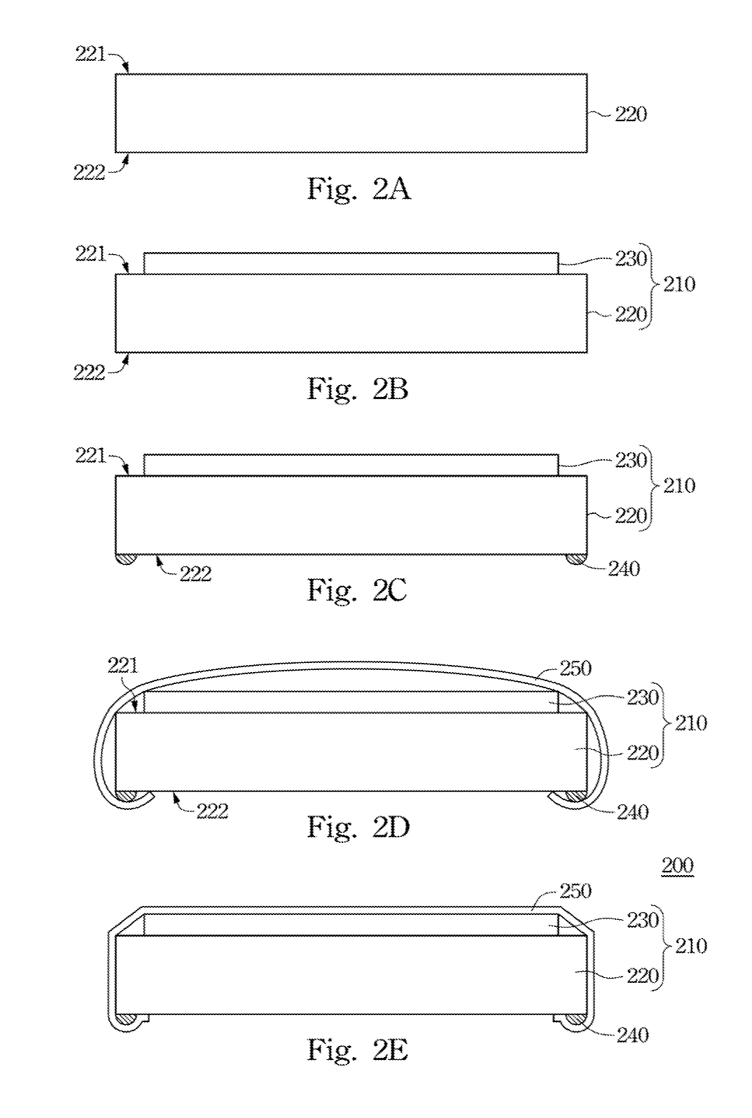

In the detailed description of the disclosure, first, the method of manufacturing a photovoltaic panel is elaborated with reference to FIG. 1 and FIGS. 2A-2E. FIG. 1 is a flow chart of a method of manufacturing a photovoltaic panel according to one embodiment of the disclosure. FIGS. 2A-2E are cross-sectional views of the photovoltaic panel in accordance with each step in FIG. 1.

As shown in step S1 and FIG. 2A, a substrate 220 is provided. The substrate 220 has a first surface 221 and an opposite second surface 222. Exemplarily, the substrate 220 is a transparent conductive oxide (TCO) glass substrate, or, in another embodiment, it is made from appropriate polymer sheets, such as DuPont™ Teflon® films, DuPont™ Teonex® polyethylene naphthalate (PEN) films and DuPont™ Melinex® ST polyester films. Alternatively, the substrate 220 is a stainless steel, aluminum or graphite substrate. Practically, any other appropriate materials that are of high transmittance, light weighted, flexible, good UV resistance, and/or sufficient mechanical strength can be used herein.

As shown in step S2 and FIG. 2B, a photovoltaic cell 230 is formed on the first surface 221 of the substrate 220, so as to form a photovoltaic unit 210. The photovoltaic cell 230 can be exemplified either by a thin film photovoltaic cell or by a crystalline silicon solar cell. The type of the photovoltaic cell 230 is not limited in the disclosure, as well as the technique of forming the photovoltaic cell 230. The photovoltaic cell 230 may be deposited onto the substrate 220 by known depositing methods, such as chemical vapor deposition (CVD), physical vapor deposition (PVD), sputtering, or any other methods known to a person skilled in the art, which is not limited in the disclosure.

Optionally, in the present embodiment, the method of manufacturing the photovoltaic panel further includes a step of applying a sealant after the photovoltaic cell 230 is formed on the substrate 220. As shown in FIG. 2C, the sealant 240 is applied near the edges of the second surface 222, so as to seal a protective polymer layer in the subsequent step. The protective polymer layer will later be elaborated. Although the sealant 240 is exemplified by applying on the second surface 222, the disposition of the sealant 240 is not limited thereto. In another embodiment, the sealant 240 is disposed near the edges of the first surface 221. In fact, other dispositions of the sealant 240 at or near the edges of the first surface 221 or the second surface 222 may be acceptable in the disclosure, as long as the sealant 240 is situated between the substrate 220 and the protective polymer layer.

On the other hand, The exemplary materials for the sealant 240 includes polyisobutylene (PIB), butyl rubber, VAMAC.RTM., ethylene acrylic elastomers, Hypalon.RTM., and chlorosulfonated polyethylene. The materials are for exemplifications only, and are not intended to limit the scope of the disclosure.

The method of manufacturing the photovoltaic panel moves on to step S3 with reference to FIG. 2D, wrapping a protective polymer layer 250 around the photovoltaic unit 210 with a portion of the protective polymer layer 250 extended beyond the first surface 221 of the substrate 220. Practically, the portion of the protective polymer layer 250 is folded toward the second surface 222 of the substrate 220 to cover the edges of the second surface 222. As shown in FIG. 2D, the photovoltaic cell 230 is covered by the protective polymer layer 250 and the sealant 240 is overlaid with the protective polymer layer 250. The protective polymer layer 250 is a heat-shrink film that reduces its volume once heated, so as to form tight contact with the object wrapped inside, i.e. the photovoltaic unit 210. In one embodiment, the protective polymer layer 250 includes a material selected from the group consisting of polyvinylchloride (PVC), polypropylene (PP), polyethylene (PE), polyethylene terephthalate (PET), polystyrene (PS), acrylonitrile-butadiene-styrene terpolymer (ABS), polycarbonate (PC), polylactic acid (PLA), and any combinations thereof. The materials are for exemplifications only, and are not intended to limit the scope of the disclosure. Any other appropriate heat-shrink materials may be used in the disclosure.

After wrapping the protective polymer layer 250, step S4 is performed. In step S4, the protective polymer layer 250 is thermal treated so as to shrink the protective polymer layer 250, resulting in tight fitting of the protective polymer layer 250 around the photovoltaic unit 210 as shown in FIG. 2E. The portion of the protective polymer layer 250 extended beyond the first surface 221 is sealed around the edges of the second surface 222. In the present embodiment, the sealant 240 further facilitates the sealing of the protective polymer layer 250. Practically, the photovoltaic unit 210 wrapped in the protective polymer layer 250 undergoes the heat treatment in an oven or through a heating tunnel. The oven may heat several photovoltaic units 210 at once in a batch process, while the heating tunnel may serially heat several photovoltaic units 210 in a continuous process.

After thermal treating the protective polymer layer 250 to achieve the tight fitting of the protective polymer layer 250 around the photovoltaic unit 210, a photovoltaic panel 200 according to one embodiment of the invention is completed. The photovoltaic panel 200 is used for converting incoming light beams into electrical energy. Optionally, a step of trimming the thermal treated protective polymer layer 250 may be further performed, so as to maintain the aesthetic of the photovoltaic panel 200. Afterwards, the subsequent steps, such as installing a junction box and electrically connecting the junction box, can be performed.

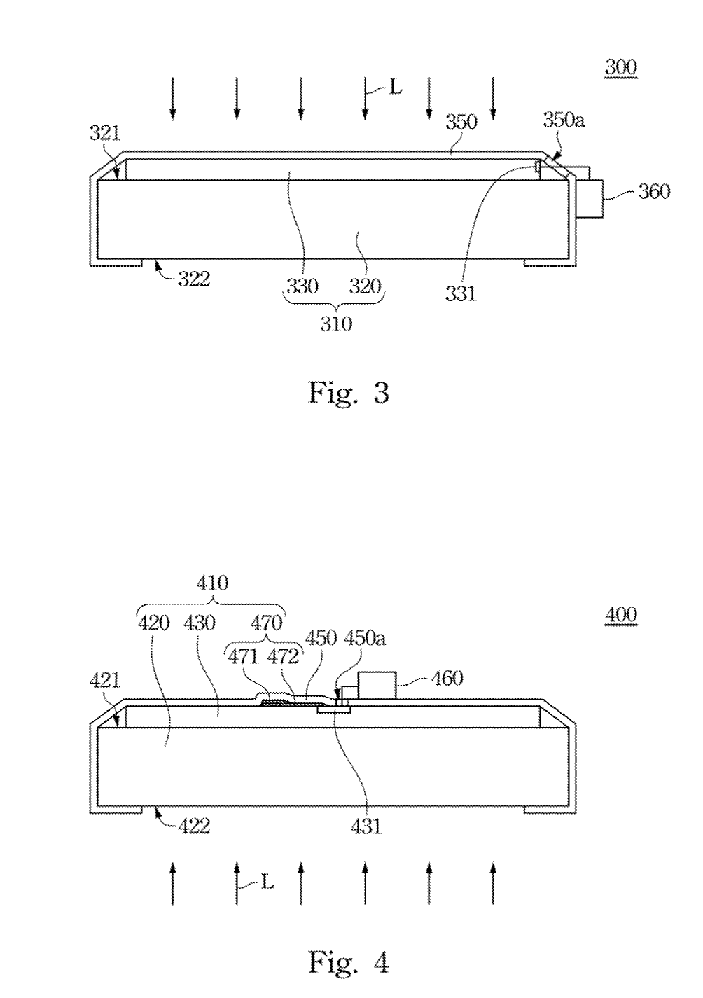

FIG. 3 is a cross-sectional view of a photovoltaic panel according to another embodiment of the disclosure. Generally, the method of manufacturing the photovoltaic panel 300 is similar to that of the aforementioned photovoltaic panel 100 with reference to FIG. 1 and FIGS. 2A-2E, and will not be repeated here. The photovoltaic panel 300 that is used for converting several incoming light beams L into electrical energy includes a photovoltaic unit 310 and a protective polymer layer 350. The photovoltaic unit 310 is characterized in having a single substrate 320 and includes a photovoltaic cell 330 disposed on the substrate 320. The protective polymer layer 350 wraps the photovoltaic unit 310 and is sealed around the edges of a surface of the substrate 320.

More specifically, the substrate 320 has a first surface 321 that faces the incoming light beams L and an opposite second surface 322. The protective polymer layer 350 is sealed around the edges of the second surface 322. The photovoltaic cell 330 is disposed on the first surface 321 and includes an electric contact 331 for connecting to an electric junction box 360 of the photovoltaic panel 300. In the present embodiment, the electric junction box 360 is disposed next to the photovoltaic unit 310. The protective polymer layer 350 has an opening 350a from which the electric contact 331 is exposed and via which the electric contact 331 is connected to the electric junction box 360, so as to output the electrical energy.

FIG. 4 is a cross-sectional view of a photovoltaic panel according to a further embodiment of the disclosure. Generally, the method of manufacturing the photovoltaic panel 400 is similar to that of the aforementioned photovoltaic panel 100 with reference to FIG. 1 and FIGS. 2A-2E, and will not be repeated here. The photovoltaic panel 400 that is used for converting several incoming light beams L into electrical energy includes a photovoltaic unit 410 and a protective polymer layer 450. The photovoltaic unit 410 includes a single substrate 420 and a photovoltaic cell 430 disposed on the substrate 420. The protective polymer layer 450 wraps the photovoltaic unit 410 and is sealed around the edges of a surface of the substrate 420.

In the present embodiment, the second surface 422 of the substrate 420 faces the incoming light beams L. The photovoltaic cell 430 is disposed on the first surface 421 of the substrate 420 and includes an electric contact 431 for connecting to an electric junction box 460 of the photovoltaic panel 400. The electric junction box 460 is disposed on the photovoltaic unit 410. The protective polymer layer 450 has an opening 450a from which the electric contact 431 is exposed and via which the electric contact 431 is connected to the electric junction box 460, so as to output the electrical energy.

More specifically, the photovoltaic unit 410 further includes an electric circuitry 470 connected with the electric contact 431, and the protective polymer layer 450 covers the electric circuitry 470 to protect the electric circuitry 470. Exemplarily, the electric circuitry 470 includes a flexible circuit 472 and a metal wiring 471 to transmit and/or to manipulate electrical signals.

In the above-described photovoltaic panel and the method of manufacturing the same, the photovoltaic unit is characterized in having a single substrate and is wrapped in the protective polymer layer. The structure of the photovoltaic panel is simplified, and the cost is lowered accordingly. The protective polymer layer wraps and forms a tight fitting around the photovoltaic unit through a thermal treating process, hence simplifying the manufacturing process and increasing the manufacturing efficiency.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A photovoltaic panel for converting a plurality of incoming light beams into electrical energy, comprising:
a photovoltaic unit characterized in having a single substrate and comprising:
the single substrate having a first surface and an opposite second surface; and
a photovoltaic cell disposed on the first surface of the single substrate; and
a protective polymer layer wrapping the photovoltaic unit and being sealed around the edges of the second surface of the single substrate.

2. The photovoltaic panel of claim 1, wherein the protective polymer layer is a heat-shrink film.

3. The photovoltaic panel of claim 1, wherein the protective polymer layer comprises a material selected from the group consisting of polyvinylchloride (PVC), polypropylene (PP), polyethylene (PE), polyethylene terephthalate (PET), polystyrene (PS), acrylonitrile-butadiene-styrene terpolymer (ABS), polycarbonate (PC), polylactic acid (PLA), and any combinations thereof.

4. The photovoltaic panel of claim 1, wherein the first surface faces the incoming light beams and the photovoltaic cell comprises:
an electric contact for connecting to an electric junction box disposed next to the photovoltaic unit, wherein the protective polymer layer comprises an opening from which the electric contact is exposed.

5. The photovoltaic panel of claim 1, wherein the second surface faces the incoming light beams and the photovoltaic cell comprises:
an electric contact for connecting to an electric junction box disposed on the photovoltaic unit, wherein the protective polymer layer comprises an opening from which the electric contact is exposed.

6. The photovoltaic panel of claim 5, wherein the photovoltaic unit further comprises:
an electric circuitry connected to the electric contact, and the protective polymer layer covers the electric circuitry.

7. The photovoltaic panel of claim 6, wherein the electric circuitry comprises a flexible circuit and a metal wiring.

8. The photovoltaic panel of claim 1, further comprising:
a sealant disposed around the edges of the first surface and sandwiched between the protective polymer layer and the first surface.

9. The photovoltaic panel of claim 1, further comprising:
a sealant disposed around the edges of the second surface and sandwiched between the protective polymer layer and the first surface

10. The photovoltaic panel of claim I, wherein the photovoltaic cell is a crystalline silicon solar cell or a thin film solar cell.

11. The photovoltaic panel of claim 1, wherein the single substrate is a glass substrate, polymer sheet, stainless steel, aluminum or graphite.

12. A method of manufacturing a photovoltaic panel, comprising:
providing a substrate having a first surface and an opposite second surface;
forming a photovoltaic cell on the first surface of the substrate to form a photovoltaic unit;
wrapping a protective polymer layer around the photovoltaic unit with a portion of the protective polymer layer extended beyond the first surface of the substrate; and
thermal treating the protective polymer layer so as to shrink the protective polymer layer and thereby sealing the portion of the protective polymer layer extended beyond the first surface around the edges of the second surface.

13. The method of claim 12, further comprising:
applying a sealant at or near the edges of the first surface prior to the step of wrapping the protective polymer layer around the photovoltaic unit.

14. The method of claim 12, further comprising:
applying a sealant at or near the edges of the second surface prior to the step of wrapping the protective polymer layer around the photovoltaic unit.

15. The method of claim 12, further comprising:
trimming the thermal treated protective polymer layer.
